(19) United States
(12) Patent Application Publication
(10) Pub. No.: US 2016/0187412 A1
(43) Pub. Date: Jun. 30, 2016

(54) METHOD AND DEVICE FOR MONITORING A PROTECTIVE CONDUCTOR CONNECTION

(71) Applicant: Bender GmbH & Co. KG, Gruenberg (DE)

(72) Inventors: Bernd Haeuslein, Nuernberg (DE); Helmut Becker, Gruenberg (DE); Carsten Hartmann, Schotten (DE)

(21) Appl. No.: 14/964,703

(22) Filed: Dec. 10, 2015

(30) Foreign Application Priority Data
Dec. 30, 2014 (DE) 10 2014 019 397.7

(51) Int. Cl. G01R 31/08; G01R 31/04

(52) U.S. Cl. CPC G01R 31/085; G01R 31/041

(57) ABSTRACT

The invention relates to a method and to a device for monitoring a protective conductor connection of an electrical supply line, the supply line running between a feeding point and a load-side connection.

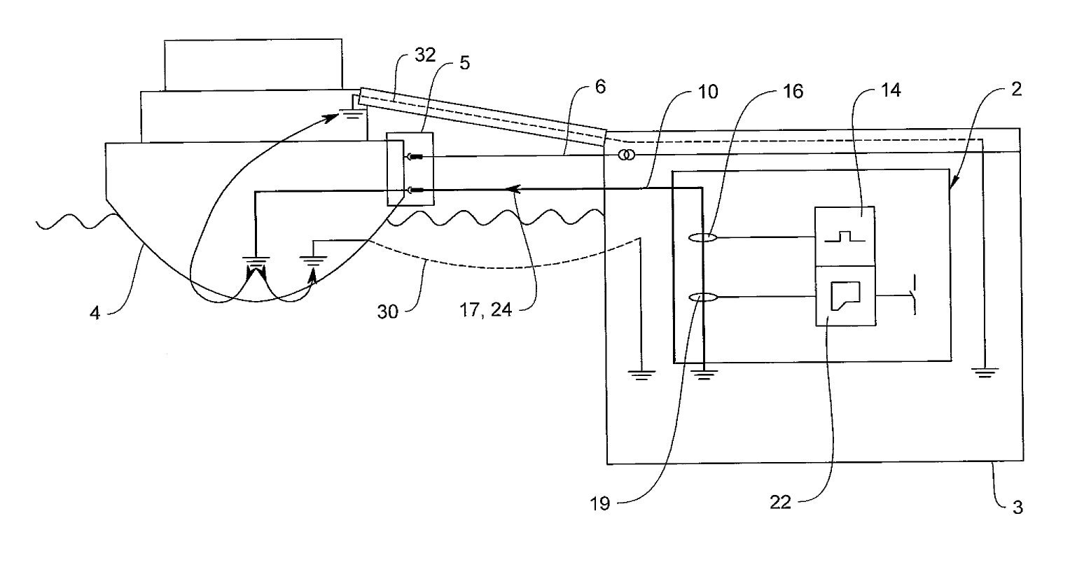

The invention is based on the generation and inductive feeding of a test current into the protective conductor connection and on the registration of a current flowing in the protective conductor connection.

This application claims the benefit of German Patent Application No. 10 2014 019 397.7, the disclosure of which is incorporated herein by reference.

### TECHNICAL FIELD

The invention relates to a method for monitoring a protective conductor connection of an electrical supply line, the supply line running between a feeding point and a load-side connection, comprising the method steps of generating and feeding a test current to be performed at the feeding point.

Furthermore, the invention relates to a device for monitoring a protective conductor connection of an electrical supply line, the supply line running between a feeding point and a load-side connection, composed of a test current generator for generating a test current and of a coupling circuit for feeding the test current.

### BACKGROUND

Loop monitoring devices for monitoring loop resistances and protective conductor connections are known. For example, devices of this kind are used to detect a protective conductor break in electrical installations. For this purpose, a monitoring device comprising a test current generator is connected, via a monitoring line or also directly, to the grounded body of an electric load on the one hand and to a ground connection on the other hand. The circuit closes via the protective conductor, the current measurable in the monitoring device thus providing a conclusion regarding the continuity of the protective conductor connection. If the measured current falls short of a preset response value, which is equivalent to a loop resistance being exceeded, an alarm is triggered.

One problem of this method is multiple grounding, which occurs when instead of the test current circuit closing solely via the protective conductor back to the test current generator, there are additional parallel current paths, which may lead to an incorrect evaluation of the current flow. Thus, in case of unfavorable resistance conditions, the test current portion flowing back in the protective conductor current may not be sufficiently large to allow a secure conclusion regarding the functionality of the protective conductor.

Additionally, interference effects occur, such as in the form of leakage currents, which interfere with the test current to be measured on the protective conductor and distort the measuring result. These problems and their solutions in accordance with the invention will be explained in the following based on the example of a shore connection for ships.

Efforts are being made to provide the electrical energy supply for ships from the shore during loading and unloading of ships in international ports. In this way, the on-board power units may be shut down, which saves fuel and reduces pollution for the environment and especially also for the residents in the area surrounding the port.

In a shore connection of this kind, a reliable protective conductor connection with the ship must be ensured before switching to shore power and while power is being supplied from shore.

With the known means for loop monitoring, reliable monitoring of the protective conductor connection cannot be ensured in this specific application because these devices do not take into account parallel ground connections, such as via the salt water and the gangways, which means that it is impossible to detect whether the check loop actually closes via the intended protective ground connection only. Hence, improper release of the supply voltage and an interrupted protective conductor during feeding must be avoided.

### SUMMARY

Therefore, the present invention is based on the object of developing a method and a device that ensure reliable monitoring of a protective conductor connection.

With regard to a method, this object is attained in connection with the preamble of claim 1 in that the test current is fed directly into the protective conductor connection to be monitored and a protective conductor current flowing in the protective conductor connection is registered.

Owing to the fact that according to the invention the test current is coupled directly into the protective conductor connection at the feeding point, it is advantageously ensured that a precisely adjustable, sufficiently large test current is available, which flows entirely in the protective conductor connection to be monitored if the protective conductor connection functions correctly, the protective conductor having to be insulated and connected according to regulations.

For evaluation in view of detection of a faulty or interrupted protective conductor connection, the protective conductor current flowing in the protective conductor connection is selectively registered. In this way, it can be determined independently of additional parallel ground connections whether the protective conductor connection actually constitutes the desired main grounding connection. Thus, it is precluded that undesired multiple groundings “simulate” a seemingly regular protective conductor connection.

Advantageously, the test current is fed by way of inductive coupling. The inductive (transformer) coupling allows the test current to be fed free of potential, i.e. independently of the potential present on the protective conductor connection to be monitored due to operation.

Furthermore, the protective conductor current is registered by way of inductive coupling. As in the case of test current feeding, the inductive (transformer) coupling allows the protective conductor current to be registered free of potential.

Advantageously, the registered protective conductor current is evaluated in its entirety so as to detect a faulty protective conductor connection. Under the assumption that in case of a sufficiently large current flow to be expected according to the electrical parameters of the supply line, a fault-free protective conductor connection can be assumed, the entire registered protective conductor current is subjected to evaluation with a view to a conclusion regarding the state of the protective conductor connection. Thus, the leakage currents present via the protective conductor connection due to operation are also taken as an indication that the protective conductor is connected with low resistance, i.e. that there is a functioning protective conductor connection.

Preferably, an alarm is issued if the protective conductor current falls short of an adjustable response value. If it is found during evaluation of the registered protective conductor current that it is below a protective conductor current response value, i.e. below a settable trigger threshold, this is indicative of an interruption of the protective conductor or at least of a faulty protective conductor connection, and an alarm is issued.

Advantageously, the method described above is implemented in connection with monitoring of the protective conductor in a shore connection for ships.

In particular in the course of worldwide standardization of the shore connection of ships, a reliable protective conductor connection of the electrical supply line during shore feeding is of increasing importance.

However, the present invention is not limited to this specific application. There are other advantageous applications in electrical installations and electrical equipment, in particular also in the operation of electrical machines where parallel multiple groundings make monitoring of a protective conductor connection difficult.

Since the subsequently described monitoring device is an implementation of the claimed method, the aforementioned advantageous effects of the method analogously also apply to the claimed device.

Thus, with regard to a device, the object is attained in connection with the preamble of claim 7 in that the coupling circuit is coupled with the protective conductor connection so as to feed the test current directly into the protective conductor connection and that a registration device is coupled with the protective conductor connection to register a protective conductor current.

The coupling circuit, which is coupled with the protective conductor connection, allows feeding of the test current in a simple manner such that—under the condition of an insulated protective conductor connected according to regulations—a test current of a predetermined size flows into the protective conductor.

The registration device is coupled with the protective conductor connection and thus allows registering the entire protective conductor current. The fed test current flowing entirely in the protective conductor, together with the leakage currents present due to operation, forms the registered (total) protective conductor current that is subjected to evaluation.

In an advantageous embodiment, the coupling circuit is realized as an inductive coupling circuit for feeding the test current into the protective conductor connection.

The test current can be fed into the protective conductor connection free of potential through the inductive coupling circuit (current transformer).

Advantageously, the registration device is realized as a measuring current transformer.

To register the protective conductor current, the registration device is realized as a measuring current transformer whose transformer core encloses the protective conductor connection. This embodiment allows simple and secure potential-free current measurement of the protective conductor current.

Furthermore, the monitoring device comprises an evaluation device for evaluating the registered protective conductor current so as to detect a faulty protective conductor connection.

In the evaluation device, the entire registered protective conductor current is evaluated so as to assess the functionality of the protective conductor connection.

### BRIEF DESCRIPTION OF THE DRAWING FIGURE

Other advantageous embodiment features become apparent from the following description and from the drawing, which illustrates a preferred embodiment of the invention with the aid of an example. In the drawing:

FIGURE: shows a monitoring device according to the invention in conjunction with a shore connection for ships.

Using the example of a shore connection for ships 4, the FIGURE shows a schematic illustration of an application for the method according to the invention including an embodiment of the monitoring device 2 implementing the method.

The ship 4 is connected to a feeding point 3 via a load-side connection 5 and an electrical supply line 6 toward the main power supply. The load-side connection 5 further comprises a protective conductor connection 10 (protective conductor) to be monitored.

The monitoring device 2 arranged at the feeding point 3 comprises a test current generator 14 for generating a test current 17, a coupling circuit 16, a registration device 19 and an evaluation device 22.

The test current 17 is inductively fed into the protective conductor connection 10 via the coupling circuit 16. The registration device 19 registers the protective conductor current 24 flowing on the protective conductor connection 10, the fed test current 17 and the leakage currents flowing due to operation forming a part of the registered protective conductor current 24. The registration device 19 is preferably realized as a measuring current transformer. In the evaluation device 22, the (total) protective conductor current 24 registered by the registration device 19 is evaluated so as to detect a faulty, i.e. insufficiently low-resistance protective conductor connection 10 based on the size of the registered protective conductor current 24.

In the illustrated application example of the shore connection for ships, the test current 17 fed into the protective conductor connection at the feeding point 3 can take several undefined paths back to the test current generator 14. For example, the test current circuit can close via the electrically conductive salt water 30 or via a gangway 32. However, since the test current 17 is fed directly into the protective conductor connection 10, it may be determined based on the registered protective conductor current 24 actually flowing in the protective conductor connection 10 whether a fault-free protective conductor connection 10 exists.

1. A method for monitoring a protective conductor connection (10) of an electrical supply line (6), the supply line (6) running between a feeding point (3) and a load-side connection (5), comprising the method steps of generating and feeding a test current (17) to be performed at the feeding point (3),
characterized in that
the test current (17) is fed directly into the protective conductor connection (10) to be monitored and a protective conductor current (24) flowing in the protective conductor connection is registered.

2. The method according to claim 1,
characterized in that
the test current (17) is fed by way of inductive coupling.

3. The method according to claim 1,
characterized in that
the protective conductor current (24) is registered by way of inductive coupling.

4. The method according to claim 1,
characterized in that
the registered protective conductor current (24) is evaluated in its entirety so as to detect a faulty protective conductor connection.

5. The method according to claim 1,
characterized in that
an alarm is issued if the protective conductor current falls short of an adjustable response value.

6. The method according to claim 1,
characterized by
being implemented in connection with monitoring of the protective conductor in a shore connection for ships (4).

7. A device for monitoring a protective conductor connection (10) of an electrical supply line (6), the supply line (6) running between a feeding point (3) and a load-side connection (5), composed of a test current generator (14) for generating a test current (17) and of a coupling circuit (16) for feeding the test current (17),
characterized in that
the coupling circuit (16) is coupled with the protective conductor connection (10) so as to feed the test current (17) directly into the protective conductor connection (10) and that a registration device (19) is coupled with the protective conductor connection (10) so as to register a protective conductor current (24).

8. The monitoring device according to claim 7,
characterized in that
the coupling circuit (16) is realized as an inductive coupling circuit (16) for feeding the test current (17) into the protective conductor connection (10).

9. The monitoring device according to claim 7,
characterized in that
the registration device (19) is realized as a measuring current transformer.

10. The monitoring device according to claim 7,
characterized by
an evaluation device (22) for evaluating the registered protective conductor current (24) so as to detect a faulty protective conductor connection.
